(19) United States
(12) Patent Application Publication
(10) Pub. No.: US 2007/0051314 A1
(43) Pub. Date: Mar. 8, 2007

(54) MOVABLE TRANSFER CHAMBER AND SUBSTRATE-TREATING APPARATUS INCLUDING THE SAME

(75) Inventors: Jae-Wook Choi, Seoul, 138-738 (KR); Young-Rok Kim, Gyunggi-do, 464-892 (KR)

Correspondence Address: MARGER JOHNSON & MCCOLLOM, P.C., 210 SW MORRISON STREET, SUITE 400, PORTLAND, OR, 97204, US

(73) Assignee: JUSUNG Engineering Co., Ltd., Gyunggi-do, (KR)

(21) Appl. No.: 11/470,946

(22) Filed: Sep. 7, 2006

(30) Foreign Application Priority Data
Sep. 8, 2005 (KR) 2005-0083650
Nov. 28, 2005 (KR) 2005-0114011

(51) Int. Cl. C23F 1/00; C23C 16/00

(52) U.S. Cl. 118/719; 156/345.31

(57) ABSTRACT

A substrate-treating apparatus includes: at least one process chamber treating a substrate; a movable transfer chamber movable adjacent to the process chamber; a driving means moving the movable transfer chamber; and a connection means combining and separating the process chamber and the movable transfer chamber.

The present invention claims the benefit of Korean Patent Application No. 10-2005-0083650 filed in Korea on Sep. 8, 2005 and Korean Patent Application No. 10-2005-0114011 filed in Korea on Nov. 28, 2005, which are hereby incorporated by references.

### BACKGROUND OF THE INVENTION

1. Field of the Invention

The present invention relates to a movable transfer chamber, and more particularly, to a movable transfer chamber for a large-sized substrate for a display device and a semiconductor device and a substrate-treating apparatus including the movable transfer chamber.

2. Discussion of the Related Art

In general, a fabrication process for a display device and a semiconductor device includes a deposition step where a thin film of a specific material is formed on a substrate such as a glass and a wafer, a photolithography step where a portion of a thin film is selectively exposed through a photosensitive material, and an etching step where a portion of a thin film is selectively removed. These steps are performed in a chamber under an optimum process condition for the corresponding step. Recently, a cluster type substrate-treating apparatus where a process chamber, a load lock chamber and a transfer chamber are integrated has been widely used to treat a large number of substrates for a short process time. A substrate is treated in the process chamber, and the substrate is input and output through the load lock chamber. In addition, the substrate is transferred between the process chamber and the load lock chamber by the transfer chamber.

FIG. 1 is a schematic plane view showing a cluster type substrate-treating apparatus according to the related art. In FIG. 1, a cluster type substrate-treating apparatus includes a transfer chamber 70, a plurality of process chambers 80, a first load lock chamber 40, a second load lock chamber 50, a transport unit 10, a first load port 20 and a second load port 30. The plurality of process chambers 80 and the first and second load lock chambers 40 and 50 are connected to side portions of the transfer chamber 70. In addition, the transport unit 10 is connected to side portions of the first and second load lock chambers 40 and 50, and the first and second load ports 20 and 30 are connected to side portions of the transport unit 10.

A thin film is deposited on a substrate or a thin film on a substrate is etched in each process chamber 80 under a high vacuum condition. The transfer chamber 70 includes a transfer robot 72 and the substrate is transferred between the process chambers 80 or between the process chamber 80 and one of the first and second load lock chambers 40 and 50 by the transfer robot 72. The transfer chamber 70 also has a vacuum condition. A slot valve is disposed between the process chamber 80 and the transfer chamber 70 to open and close a transfer path. Since the transfer chamber 70 has a vacuum condition and the transport unit 10 has an atmospheric pressure condition, the first and second load lock chambers 40 and 50 are used as buffer spaces between the transfer chamber 70 and the transport unit 10. While the substrate is input and output, the first and second load lock chambers 40 and 50 alternate between the vacuum condition and the atmospheric pressure condition. A slot valve is also disposed between the transfer chamber 70 and the load lock chambers 40 and 50 and between the load lock chambers 40 and 50 and the transport unit 10.

The plurality of process chambers 80 and the load lock chambers 40 and 50 are disposed along a circumference of the transfer chamber 70. In addition, the transfer robot 72 rotates in the transfer chamber 70. Accordingly, a great volume of the transfer chamber 70 is required. As a result, a footprint and a cost for the substrate-treating apparatus increase. Moreover, since the plurality of process chambers 80 and the load lock chambers 40 and 50 are connected to side portions of the transfer chamber 70, the disposition of the substrate-treating apparatus is limited and utilization of space is restricted.

FIG. 2 is a schematic plane view showing an in-line type substrate-treating apparatus according to the related art. In FIG. 2, the in-line type substrate-treating apparatus includes a transfer chamber 70, a plurality of process chambers 80 and a load lock chamber 40. The plurality of process chambers 80 and the load lock chamber 40 in a line are connected to a side portion of the transfer chamber 70. In addition, a transfer robot 72 moves along a straight line to transfer a substrate. The transfer chamber 70 having a vacuum condition includes the transfer robot 72, a driving means for the transfer robot 72 and a guide rail 74 guiding the straight movement of the transfer robot 72. The transfer robot 72 moves along the guide rail 74 straightly with respect to the plurality of process chambers 80 and the load lock chamber 40. The transfer robot 72 exchanges a substrate between the load lock chamber 40 and the process chamber 80.

In the in-line type substrate-treating apparatus, as the number of the plurality of process chambers 80 increases, the size of the transfer chamber 70 increases. Since the transfer chamber 70 has a vacuum condition, increase in a size of the transfer chamber 70 is limited. As a result, the number of the plurality of process chambers 80 connected to the transfer chamber 70 is restricted and a capability of treating substrates of the in-line type substrate-treating apparatus is limited.

### SUMMARY OF THE INVENTION

Accordingly, the present invention is directed to a transfer chamber and an apparatus including the transfer chamber that substantially obviates one or more of the problems due to limitations and disadvantages of the related art.

An object of the present invention is to provide a transfer chamber where a plurality of process chambers and a load lock chamber are connected without increase of a chamber volume and a footprint of a substrate-treating apparatus.

Another object of the present invention is to provide a substrate-treating apparatus where a substrate-treating capability is improved and a disposition of a transfer chamber, a plurality of process chambers and a load lock chamber is improved.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, a substrate-treating apparatus includes: at least one process chamber treating a substrate; a movable transfer chamber movable adjacent to the process chamber; a driving means moving the movable transfer chamber; and a connection means combining and separating the process chamber and the movable transfer chamber.

In another aspect, a substrate-treating apparatus includes: first and second guide rails parallel to each other; first and second movable transfer chambers movable along the first and second guide rails, respectively; a first process chamber between the first and second guide rails, the first process chamber including a first gate facing the first guide rail; a second process chamber between the first and second guide rails, the second process chamber including a second gate facing the second guide rail, the first and second process chambers having a space opposite to the first and second gates in common; a first load lock chamber disposed along the first guide rail; a second load lock chamber disposed along the second guide rail; and a transport unit between the first and second load lock chambers.

In another aspect, a movable transfer chamber includes: a chamber body having a gate for a substrate; and a substrate-transferring unit in the chamber body, wherein the movable transfer chamber is movable with respect to a process chamber and is combined with the process chamber under a vacuum condition to transfer the substrate.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a schematic plane view showing a cluster type substrate-treating apparatus according to the related art;

FIG. 2 is a schematic plane view showing an in-line type substrate-treating apparatus according to the related art;

FIG. 3 is a schematic plane view showing a substrate-treating apparatus according to a first embodiment of the present invention;

FIG. 4 is a schematic cross-sectional view showing a movable transfer chamber and a driving means for a substrate-treating apparatus according to a first embodiment of the present invention;

FIGS. 5A to 5D are schematic plane views showing an operation of a substrate-treating apparatus according to a first embodiment of the present invention;

FIGS. 6A and 6B are schematic cross-sectional views showing a separation state and a connection state, respectively, of a movable transfer chamber and a process chamber for a substrate-treating apparatus according to a first embodiment of the present invention;

FIG. 7 is a schematic cross-sectional view showing a movable transfer chamber and a driving means for a substrate-treating apparatus according to a second embodiment of the present invention;

FIGS. 8A to 8D are schematic plane views showing an operation of a substrate-treating apparatus according to a second embodiment of the present invention;

FIG. 9 is a schematic plane view showing a substrate-treating apparatus according to a third embodiment of the present invention; and

FIG. 10 is a schematic plane view showing a substrate-treating apparatus according to a fourth embodiment of the present invention.

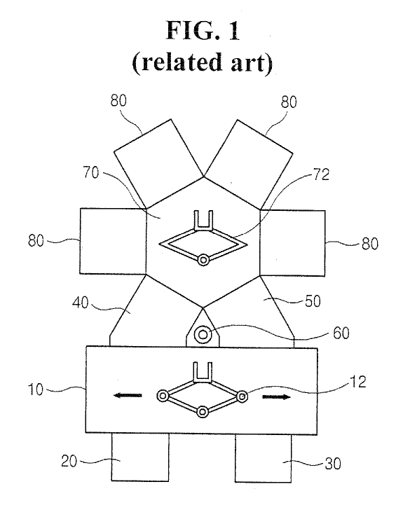

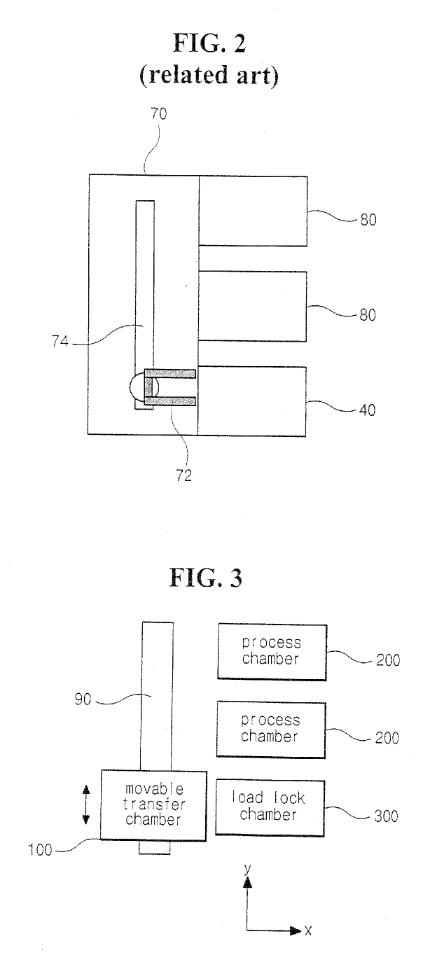

### DETAILED DESCRIPTION OF THE PREFERRED EMBODIMENTS

Reference will now be made in detail to the preferred embodiments, examples of which are illustrated in the accompanying drawings.

FIG. 3 is a schematic plane view showing a substrate-treating apparatus according to a first embodiment of the present invention.

In FIG. 3, a substrate-treating apparatus includes two process chambers 200, a load lock chamber 300 and a movable transfer chamber 100. The two process chambers 200 and the load lock chamber 300 are disposed in a line along a y-axis “y,” and the transfer chamber 100 moves along a guide rail 90 disposed at side portions of the two process chamber 200 and the load lock chamber 300. Gates (not shown) of the two process chamber 200 and the load lock chamber 300 face the guide rail 90, and a gate (not shown) of the movable transfer chamber 100 faces the two process chambers 200 and the load lock chamber 300. Accordingly, after the movable transfer chamber 100 straightly moves along the guide rail 90, the movable transfer chamber 100 stops at front of the process chamber 200 to exchange a substrate with the process chamber 200 or stops at front of the load lock chamber 300 to exchange a substrate with the load lock chamber 300.

Since an exterior of the movable transfer chamber 100, the two process chambers 200 and the load lock chamber 300 has an atmospheric pressure condition, an interior of the movable transfer chamber 100 is atmospherically separated from the exterior to keep a vacuum condition. In addition, the vacuum condition is kept using a connection means while a substrate is exchanged between the movable transfer chamber 100 and the process chamber 200 and between the movable transfer chamber 100 and the load lock chamber 300. An additional driving means is required to move the movable transfer chamber 100.

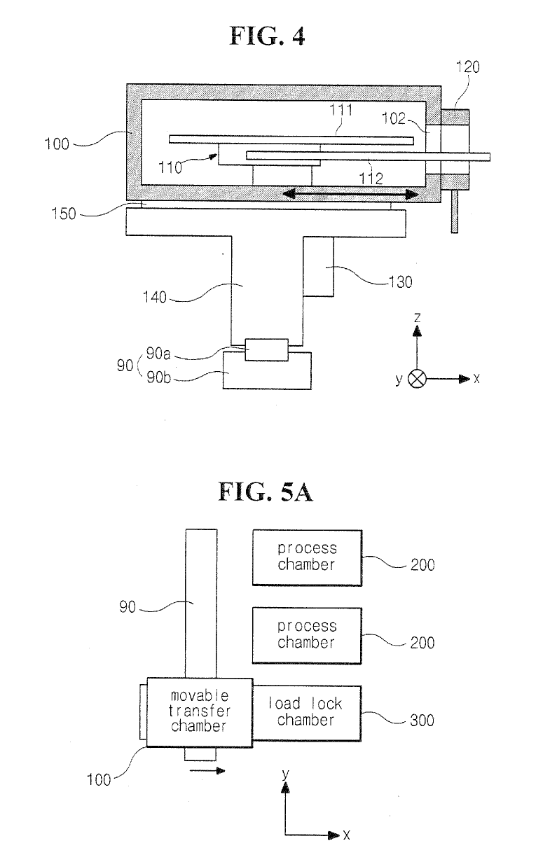

FIG. 4 is a schematic cross-sectional view showing a movable transfer chamber and a driving means for a substrate-treating apparatus according to a first embodiment of the present invention.

In FIG. 4, the movable transfer chamber 100 includes a transfer robot 110 as a substrate-transferring unit. A first gate 102 for a substrate is formed through a sidewall of the movable transfer chamber 100, and a first slot valve 120 is formed at an outer surface of the first gate 102 to open and close the first gate 102. The transfer robot 110 includes two robot arms 111 and 112 to transfer two substrates at the same time. The transfer robot 110 is connected to a robot driving unit 130 and the robot driving unit 130 is connected to a bottom of the movable transfer chamber 100. The robot driving unit 130 moves the two robot arms 111 and 112 vertically along a z-axis “z” or horizontally along an x-axis “x” to transfer a substrate through the first gate 102.

The movable transfer chamber 100 moves using a driving means including a supporting unit 140, a first guide rail 90 and a second guide rail 150. The movable transfer chamber 100 is supported by the supporting unit 140 and the supporting unit 140 is combined with the first guide rail 90. The supporting unit 140 moves on the first guide rail 90 along a y-axis “y” by a first driving unit (not shown). Accordingly, the movable transfer chamber 100 moves with the supporting unit 140 along the first guide rail 90. The first guide rail 90 includes a first rail 90a and a first rail supporting unit 90b supporting the first rail 90a.

While the movable transfer chamber 100 moves along the guide rail 90, a distance between the movable transfer chamber 100 and the process chamber 200 or between the movable transfer chamber 100 and the load lock chamber 300 is not reduced. Accordingly, a second driving unit is required to move the movable transfer chamber 100 along the x-axis “x” so that the movable transfer chamber 100 can be combined with one of the process chamber 200 and the load lock chamber 300. The second guide rail 150 is formed between the movable transfer chamber 100 and the supporting unit 140, and a second driving unit (not shown) moves the movable transfer chamber 100 on the second guide rail 150 along an x-axis “x.” The first and second guide rails 90 and 150 does not cross each other and may be disposed to be perpendicular to each other.

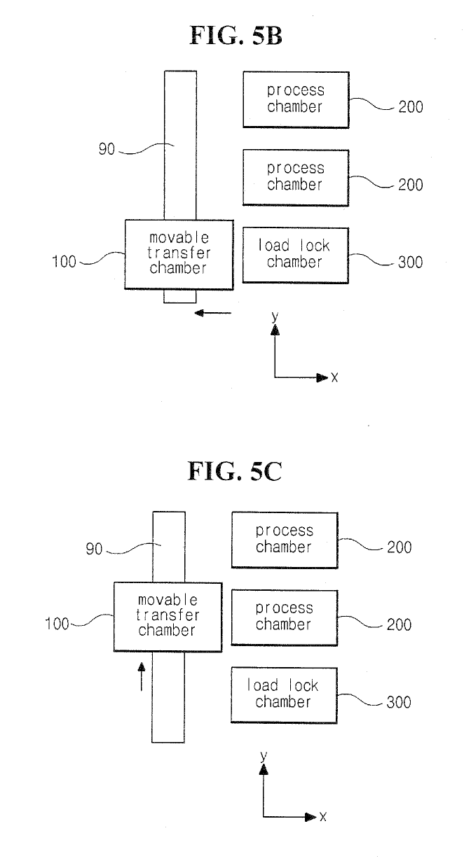

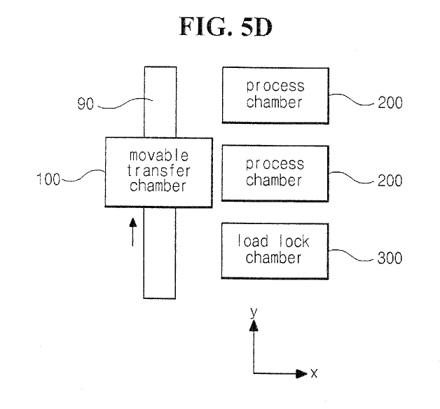

FIGS. 5A to 5D are schematic plane views showing an operation of a substrate-treating apparatus according to a first embodiment of the present invention.

In FIG. 5A, the movable transfer chamber 100 is combined with the load lock chamber 300 to exchange a substrate. The supporting unit 140 moves on the first guide rail 90 along the y-axis “y” and stops at front of the load lock chamber 300. The first driving unit (not shown) for the supporting unit 140 may include an alignment means such as a sensor to stop the movable transfer chamber 100 at an exact position. While the supporting unit 140 is fixed to the first guide rail 90, the movable transfer chamber 100 moves on the second guide rail 150 along the x-axis “x” and is combined with the load lock chamber 300. The movable transfer chamber 100 and the load lock chamber 300 are combined without breaking a vacuum condition using a connection means.

In FIG. 5B, after a substrate is exchanged between the movable transfer chamber 100 and the load lock chamber 300, the movable transfer chamber 100 moves on the second guide rail 150 along the x-axis “x” to be separated from the load lock chamber 300.

In FIG. 5C, the supporting unit 140 and the movable transfer chamber 100 move on the first guide rail 90 along the y-axis “y” and stop at front of the process chamber 200.

In FIG. 5D, while the supporting unit 140 is fixed, the movable transfer chamber 100 moves on the second guide rail 150 along the x-axis “x” and is combined with the process chamber 200. Next, a substrate is exchanged between the movable transfer chamber 100 and the process chamber 200. After completing the exchange of a substrate, the movable transfer chamber 100 and the process chamber 200 are separated from each other using the second guide rail 150 and the movable transfer chamber 100 moves on the first guide rail 90 along the y-axis “y” to reach the load lock chamber 300 for next exchange of a substrate.

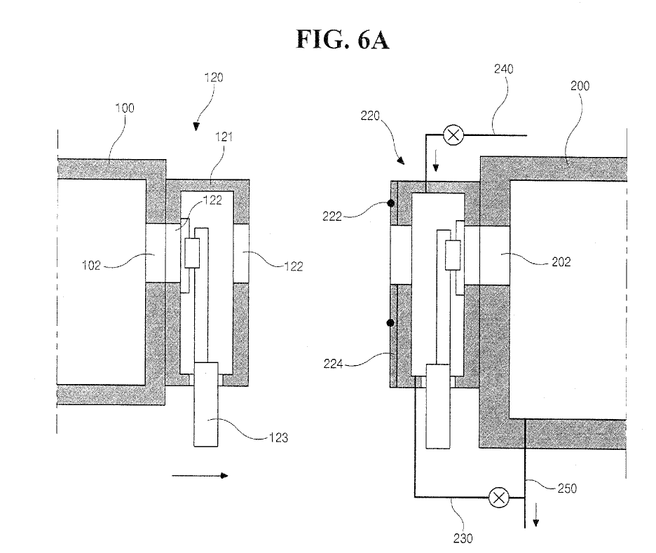

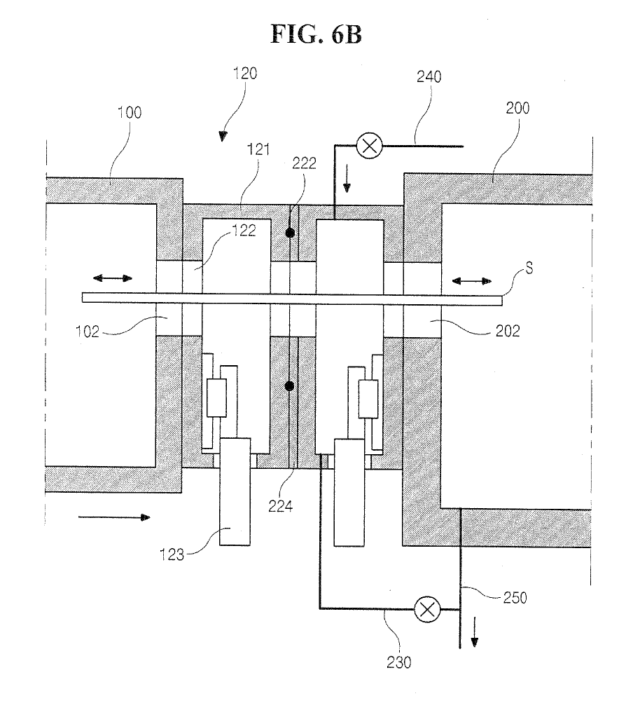

Since a substrate is exchanged without breaking a vacuum condition, a connection means is required to keep a vacuum condition while the movable transfer chamber 100 is combined with one of the load lock chamber 300 and the process chamber 200. FIGS. 6A and 6B are schematic cross-sectional views showing a separation state and a connection state, respectively, of a movable transfer chamber and a process chamber for a substrate-treating apparatus according to a first embodiment of the present invention.

In FIGS. 6A and 6B, the movable transfer chamber 100 and the process chamber 200 include a first gate 102 and a second gate 202, respectively, to transfer a substrate. A first slot valve 120 is formed on an outer surface of the movable transfer chamber 100 corresponding to the first gate 102 and a second slot valve 220 is formed on an outer surface of the process chamber 200 corresponding to the second gate 202. When the movable transfer chamber 100 approaches the process chamber 200, the first and second slot valves 120 and 220 are combined with each other.

The first slot valve 120 includes a housing 121 and a blocking means 123 in the housing 121. A first open portion 122 is formed through the housing 121, and the blocking means 123 opens and closes the first open portion 122 by a first slot valve driving unit (not shown). The blocking means 123 may move up and down for opening and closing the first open portion 122. The first open portion 122 corresponds to the first gate 102. The second slot valve 220 has a structure similar to a structure of the first slot valve 120. Even though not shown in FIGS. 6A and 6B, a third slot valve is formed on an outer surface of the load lock chamber 300.

While the first and second slot valves 120 and 220 are combined with each other, an interior of the combined first and second slot valves 120 and 220 are completely atmospherically isolated from an exterior using a sealing means on connection surfaces of the first and second slot valves 120 and 220. An O-ring 222 is formed on an outer surface of the second slot valve 220 for atmospheric isolation. The O-ring may be formed on an outer surface of the first slot valve 120 in another embodiment.

After the first and second slot valves 120 and 220 are combined with each other, a substrate is transferred between the movable transfer chamber 100 and the process chamber 200. Since the first and second gates 102 and 202 are open for transferring a substrate, impurities in the interior of the combined first and second slot valves 120 and 220 may contaminate or oxidize the movable transfer chamber 100 and the process chamber 200. Accordingly, the interior of the combined first and second slot valves 120 and 220 is evacuated by a pumping unit before the first and second gates 102 and 202 are open. A pumping line 230 may be connected to the second slot valve 220 for evacuating the interior of the combined first and second slot valves 120 and 220. When the pumping line 230 is combined with an exhaust line 250 connected to the process chamber 200, an additional pumping unit is not required.

The second slot valve 220 may open even when a pressure of the interior of the combined first and second slot valves 120 and 220 is not equal to a pressure of the process chamber 200. Accordingly, the second slot valve 220 may open when a pressure difference between the interior and the process chamber 200 is within a range of about 1 Torr to about 1000 Torr. The pressure difference may be determined within the above range according to the pressure of the process chamber 200. Similarly, the first slot valve 120 may open when a pressure difference between the interior and the movable transfer chamber 100 is within a range of about 1 Torr to about 1000 Torr.

After the interior of the combined first and second slot valves 120 and 220 is evacuated through the pumping line 230, the first and second slot valves 120 and 220 are open and a substrate is transferred between the movable transfer chamber 100 and the process chamber 200. Next, the interior of the combined first and second slot valves 120 and 220 is pressurized to be an atmospheric pressure condition for separating the movable transfer chamber 100 and the load lock chamber 200. Accordingly, a venting line 240 is connected to the second slot valve 220, and a venting gas is injected into the interior of the combined first and second slot valves 120 and 220 after closing the first and second gates 102 and 202. The pumping line 230 and the venting line 240 may be connected to the first slot valve 120 in another embodiment.

Since the first and second slot valves 120 and 220 are repeatedly attached and detached from each other, an elastic means absorbing impact may be further formed on an outer surface of one of the first and second slot valves 120 and 220 to reduce an impact due to combination. Even though the elastic means 224 is formed on an outer surface of the second slot valve 220 in FIGS. 6A and 6B, the elastic means may be formed on an outer surface of the first slot valve 120 or may be formed on both outer surface of the first and second slot valves 120 and 220 in another embodiment.

Moreover, since the movable transfer chamber 100 moves and is combined to one of the process chamber 200 and the load lock chamber 300, an alignment means that precisely adjusts the movement of the movable transfer chamber 100 is required. For example, an alignment means including a sensor may be disposed on both or one of the first and second slot valves 120 and 220, and the movement of the movable transfer chamber 100 may be adjusted by a feedback of the sensed result. Further, a physical connection guiding means (not shown) may be formed on both or one of the first and second slot valves 120 and 220 to combine the movable transfer chamber 200 with one of the process chamber 200 and the load lock chamber 300 at an exact position. Moreover, an additional pumping unit may be connected to the movable transfer chamber 100 to evacuate the movable transfer chamber 100. The movable transfer chamber 100 may include an exhaust connected to the additional pumping unit such as a vacuum pump.

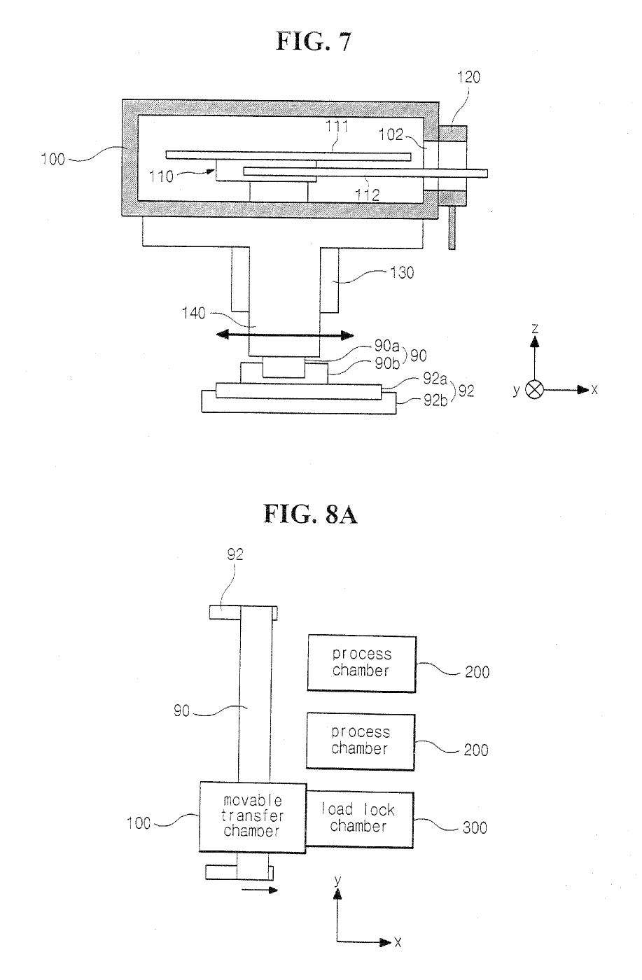

FIG. 7 is a schematic cross-sectional view showing a movable transfer chamber and a driving means for a substrate-treating apparatus according to a second embodiment of the present invention.

In FIG. 7, a movable transfer chamber 100 moves by a driving means including a supporting unit 140, a first guide rail 90 and a second guide rail 92. The movable transfer chamber 100 is supported by the supporting unit 140, and the supporting unit 140 is connected to the first guide rail 90. The movable transfer chamber 100 is combined with one of a process chamber 200 and a load lock chamber 300 by moving the first guide rail 90 along an x-axis “x.” Since an additional guide rail between the movable transfer chamber 100 and the supporting unit 140 is omitted, the supporting unit 140 is fixed to the movable transfer chamber 100. In addition, the second guide rail 92 is formed under the first guide rail 90. The first guide rail 90 is disposed along the y-axis “y” and the second guide rail 92 is disposed along the x-axis “x.” The first and second guide rails 90 and 92 may not be parallel to each other and may be perpendicular to each other.

The first guide rail 90 includes a first rail 90a and a first rail supporting unit 90b supporting the first rail 90a, and the second guide rail 92 includes a second rail 92a and a second rail supporting unit 92b supporting the second rail 92a. Since the first rail supporting unit 90b of the first guide rail 90 is combined with the second rail 92a of the second guide rail 92, the first guide rail 90 moves along the x-axis “x.” The supporting unit 140 may move on the first guide rail 90 along the y-axis “y” by a first driving unit (not shown). In addition, the first guide rail 90 may move on the second guide rail 90 along the x-axis “x” by a second driving unit (not shown). Moreover, the movable transfer chamber 100 may be combined with one of the process chamber 200 and the load lock chamber 300 using a connection means such as a slot valve.

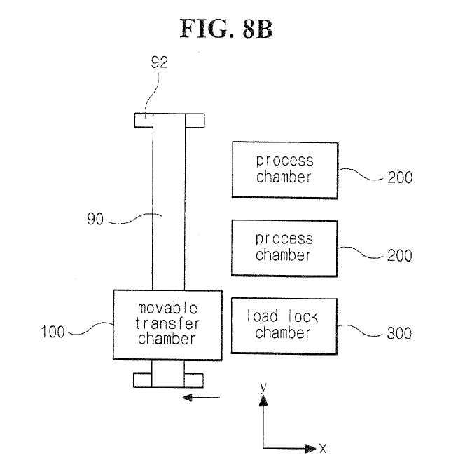

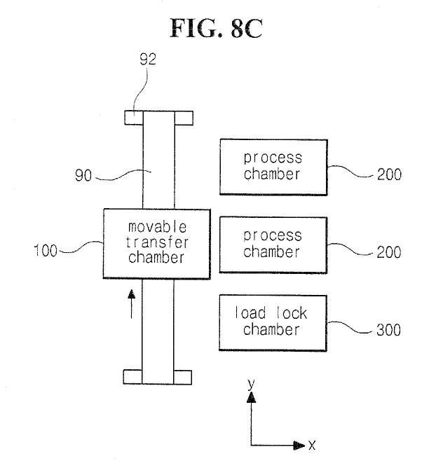

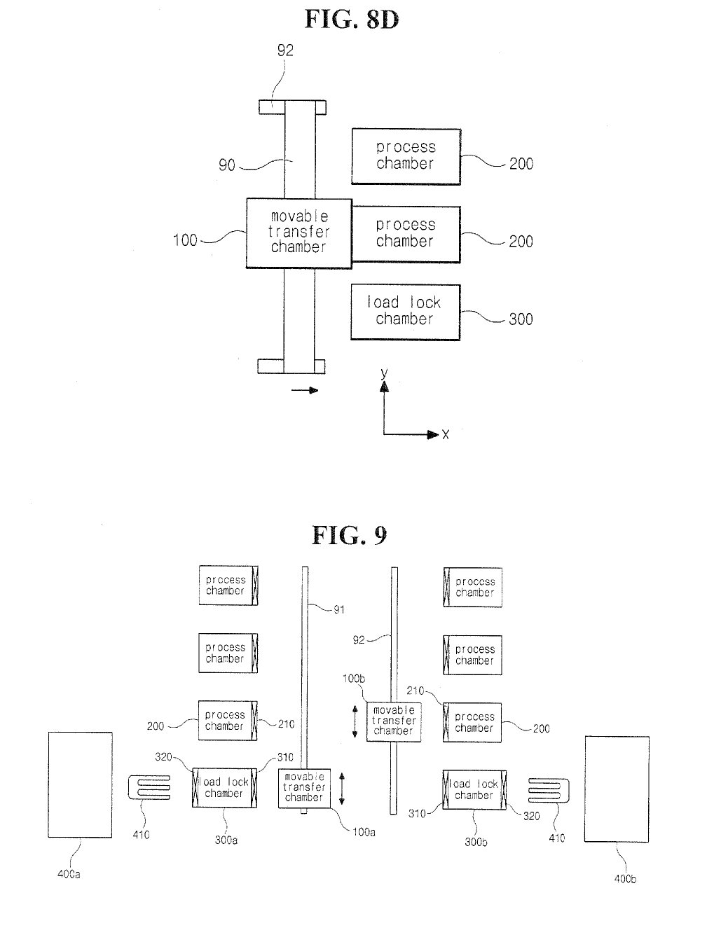

FIGS. 8A to 8D are schematic plane views showing an operation of a substrate-treating apparatus according to a second embodiment of the present invention.

In FIG. 8A, the movable transfer chamber 100 is combined with the load lock chamber 300 to exchange a substrate. The supporting unit 140 moves on the first guide rail 90 along the y-axis “y” and stops at front of the load lock chamber 300. The first driving unit (not shown) for the supporting unit 140 may include an alignment means such as a sensor to stop the movable transfer chamber 100 at an exact position. While the movable transfer chamber 100 and the supporting unit 140 are fixed to the first guide rail 90, the movable transfer chamber 100, the supporting unit 140 and the first guide rail 90 move on the second guide rail 92 along the x-axis “x” and the movable transfer chamber 100 is combined with the load lock chamber 300. The movable transfer chamber 100 and the load lock chamber 300 are combined without breaking a vacuum condition using a connection means such as a slot valve and a pumping unit such as a vacuum pump.

In FIG. 8B, after a substrate is exchanged between the movable transfer chamber 100 and the load lock chamber 300, the first guide rail 90, the supporting unit 140 and the movable transfer chamber 100 move on the second guide rail 92 along the x-axis “x” so that the movable transfer chamber 100 can be separated from the load lock chamber 300. Before the movable transfer chamber 100 and the load lock chamber 300 are separated, an interior of the slot valves may be vented to obtain an atmospheric pressure condition.

In FIG. 8C, the supporting unit 140 and the movable transfer chamber 100 move on the first guide rail 90 along the y-axis “y” and stop at front of the process chamber 200.

In FIG. 8D, while the movable transfer chamber 100 and the supporting unit 140 are fixed to the first guide rail 90, the movable transfer chamber 100, the supporting unit 140 and the first guide rail 90 move on the second guide rail 92 along the x-axis “x” and the movable transfer chamber 100 is combined with the process chamber 200. Next, a substrate is exchanged between the movable transfer chamber 100 and the process chamber 200. After completing the exchange of a substrate, the movable transfer chamber 100 and the process chamber 200 are separated from each other by moving the first guide rail 90 along the second guide rail 92, and the movable transfer chamber 100 and the supporting unit 140 move on the first guide rail 90 along the y-axis “y” to reach the load lock chamber 300 for next exchange of a substrate.

FIG. 9 is a schematic plane view showing a substrate-treating apparatus according to a third embodiment of the present invention.

In FIG. 9, a substrate-treating apparatus includes two movable transfer chambers to increase a speed of substrate treatment. The substrate-treating apparatus includes first and second movable transfer chambers 100a and 100b. The first and second movable transfer chambers 100a and 100b straightly move along first and second guide rails 91 and 92, respectively, which are parallel to each other. First and second load lock chambers 300a and 300b and a plurality of process chambers 200 are disposed outside the first and second guide rails 91 and 92. Accordingly, a chamber line including the load lock chambers and the plurality of process chambers are disposed outside the first and second guide rails 91 and 92.

The first movable transfer chamber 100a moves along the first guide rail 91 and transfers a substrate between the first load lock chamber 300a and each process chamber 200 corresponding to the first guide rail 91. Similarly, the second movable transfer chamber 100b moves along the second guide rail 92 and transfers a substrate between the second load lock chamber 300b and each process chamber 200 corresponding to the second guide rail 92. Each of the first and second movable transfer chambers 100a and 100b includes a first gate (not shown) for transferring a substrate facing the first and second guide rails 91 and 92, and each process chamber 200 includes a second gate 210 for transferring facing the first and second guide rails 91 and 92. In addition, each of the first and second load lock chambers 300a and 300b includes a third gate 310 for transferring a substrate facing the first and second guide rails 91 and 92.

Since a bare substrate is supplied to each of the first and second load lock chambers 300a and 300b from an exterior and a treated substrate is transferred to the exterior from each of the first and second load lock chambers 300a and 300b, first and second substrate supplying units 400a and 400b are disposed adjacent to the first and second load lock chambers 300a and 300b, respectively. In addition, a transport unit 410 is disposed between the first substrate supplying unit 400a and the first load lock chamber 300a and between the second substrate supplying unit 400b and the second load lock chamber 300b. Accordingly, each of the first and second load lock chambers 300a and 300b includes a fourth gate 320 for passing through the transport unit 410.

In the substrate-treating apparatus, for example, a substrate may be transferred from the first substrate supplying unit 400a to the first load lock chamber 300a through the forth gate 320. Next, the substrate may be transferred from the first load lock chamber 300a to the first movable transfer chamber 100a through the third gate 310. Similarly, a substrate may be transferred from the second substrate supplying unit 400b to the second movable transfer chamber 100b at the same time.

Furthermore, each of the first and second guide rails 91 and 92 may correspond to one or more load lock chambers to improve transfer of a substrate. When at least two load lock chambers correspond to a single guide rail, the two load lock chambers may be disposed horizontally along the single guide rail or may be disposed vertically to have different heights. In addition, when the two load lock chambers are disposed vertically with respect to the single guide rail, the two load lock chambers may move up and down by a vertical moving means so that the movable transfer chamber 100 can be connected to the two load lock chambers.

Since the first and second guide rails 91 and 92 are disposed between the two chamber lines in a substrate-treating apparatus of FIG. 9, each of the first and second load lock chambers 300a and 300b requires the substrate supplying unit 400a and 400b and the transport unit 410. As a result, elements of the substrate-treating apparatus are duplicated and efficiency of transferring a substrate is reduced. Moreover, each process chamber 200 requires a space for maintenance at opposite to the second gate 210. Since the plurality of process chambers in two chamber lines of FIG. 9 require the space for maintenance individually, utilization of space is restricted.

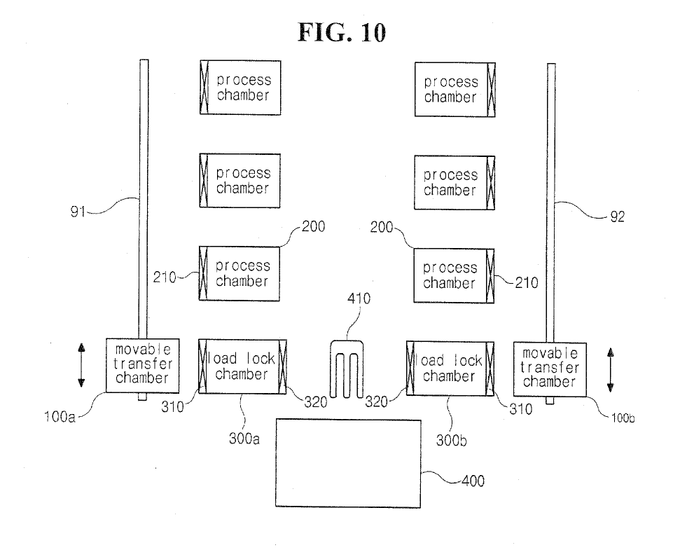

FIG. 10 is a schematic plane view showing a substrate-treating apparatus according to a fourth embodiment of the present invention.

In FIG. 10, a substrate-treating apparatus includes a plurality of process chambers 200, a first load lock chamber 300a, a second load lock chamber 300b, a first guide rail 91 and a second guide rail 92. The plurality of process chambers 200 and the first and second load lock chambers 300a and 300b are disposed as two chamber lines between the first and second guide rails 91 and 92. Each of first and second movable transfer chambers 100a and 100b has a first gate (not shown) facing the first and second load lock chambers 300a and 300b. In addition, each of the plurality of process chambers 200 has a second gate 210 facing the first and second movable transfer chambers 100a and 100b. Since the plurality of process chambers 200 in the two chamber lines have a space opposite to the second gate 210 in common for maintenance, a utilization of space is improved.

Each of the first and second load lock chambers 300a and 300b has a third gate 310 facing the first and second guide rails 91 and 92 and a fourth gate 320 opposite to the third gate 310. Since the fourth gates 320 of the first and second load lock chambers 300a and 300b faces each other and a transport unit 410 is disposed between the first and second load lock chambers 300a and 300b, a substrate in the first and second load lock chambers 300a and 300b may be transferred by the single transport unit 410. A substrate supplying unit 400 is disposed adjacent to the transport unit 410. As a result, a bare substrate may be supplied to the first and second load lock chambers 300a and 300b from the single substrate supplying unit 400 and a treated substrate may be transferred from the first and second load lock chambers 300a and 300b to the single substrate supplying unit 400. Therefore, a footprint for the substrate-treating apparatus is improved.

Consequently, in the substrate-treating apparatus according to the present invention, the movable transfer chamber are combined with or separated from one of the load lock chamber and the process chamber. The movable transfer chamber in a separation state moves and transfers a substrate between the load lock chamber and the process chamber. In addition, the movable transfer chamber in the separation state moves under a vacuum condition and a substrate is transferred between the movable transfer chamber and one of the load lock chamber and the process chamber without breaking a vacuum condition. Further, increase in the size of the movable transfer chamber is not required even when the number of the process chambers increases. Accordingly, an additional pumping unit for evacuating the movable transfer chamber is not required and a substrate-treating capability of the apparatus is improved by increasing the number of the process chambers.

Since increase in a size of the movable transfer chamber is required according to increase in a substrate size, a total volume of the movable transfer chamber, the load lock chamber and the process chamber is minimized regardless of increase in a substrate size and a pumping unit for the substrate-treating apparatus is minimized. The pumping unit for the movable transfer chamber may be omitted. Instead, the movable transfer chamber may be evacuated using a pumping unit for one of the load lock chamber and the process chamber. Therefore, the transfer chamber is simplified for easy movement. Since the size of the movable transfer chamber does not increase even when the number of the process chambers increases, utilization of space is improved for a large-sized substrate as compared with an apparatus having radially disposed process chambers.

It will be apparent to those skilled in the art that various modifications and variations can be made in a substrate-treating apparatus including a movable transfer chamber without departing from the spirit or scope of the invention. Thus, it is intended that the present invention covers the modifications and variations of this invention provided they come within the scope of the appended claims and their equivalents.

What is claimed is:

1. A substrate-treating apparatus, comprising:
at least one process chamber treating a substrate;
a movable transfer chamber movable adjacent to the process chamber;
a driving means moving the movable transfer chamber; and
a connection means combining and separating the process chamber and the movable transfer chamber.

2. The apparatus according to claim 1, wherein the at least one process chamber is a plurality of process chambers, and the plurality of process chambers are disposed as one of single chamber line and two chamber lines along the driving means.

3. The apparatus according to claim 2, further comprising at least one load lock chamber disposed as one of the single chamber line and the two chamber lines along the driving means.

4. The apparatus according to claim 3, further comprising an alignment means aligning the movable transfer chamber with respect to one of the at least one process chamber and the at least one load lock chamber.

5. The apparatus according to claim 1, wherein the movable transfer chamber maintains a vacuum condition while moving.

6. The apparatus according to claim 1, wherein the movable transfer chamber includes a transfer robot transferring at least two substrate at the same time.

7. The apparatus according to claim 1, wherein the movable transfer chamber comprises:
a first gate through which the substrate is exchanged; and
a first slot valve that opens and closes the first gate.

8. The apparatus according to claim 1, wherein the driving means comprises:
a first guide rail adjacent to the at least one process chamber;
a supporting unit supporting the at least one process chamber and moving along the first guide rail; and
a first driving unit moving the supporting unit along the first guide rail.

9. The apparatus according to claim 8, wherein the driving means further comprises:
a second guide rail between the movable transfer chamber and the supporting unit; and
a second driving unit moving the movable transfer chamber along the second guide rail.

10. The apparatus according to claim 8, wherein the driving means further comprises:
a first rail supporting unit supporting the first guide rail;
a second guide rail supporting the first rail supporting unit; and
a second driving unit moving the first rail supporting unit along the second guide.

11. The apparatus according to claim 1, wherein the connection means comprises:
a first slot valve connected to the at least one process chamber, the first slot valve opening and closing a first gate of the at least one process chamber;
a second slot valve connected to the movable transfer chamber, the second slot valve opening and closing a second gate of the movable transfer chamber;
a blocking means atmospherically isolating an inner space defined by a connection of the first and second slot valves;
a pumping line evacuating the inner space; and
a venting line ventilating the inner space.

12. The apparatus according to claim 11, further comprising an alignment means on one of outer surfaces of the first and second slot valves.

13. The apparatus according to claim 11, further comprising a connection guide means on one of outer surfaces of the first and second slot valves.

14. The apparatus according to claim 11, further comprising an elastic means absorbing an impact on one of outer surfaces of the first and second slot valves.

15. The apparatus according to claim 11, wherein the first slot valve opens when a pressure difference between the inner space and the at least one process chamber is within a range of about 1 Torr to about 1000 Torr.

16. The apparatus according to claim 11, wherein the second slot valve opens when a pressure difference between the inner space and the at least one process chamber is within a range of about 1 Torr to about 1000 Torr.

17. A substrate-treating apparatus, comprising:
first and second guide rails parallel to each other;
first and second movable transfer chambers movable along the first and second guide rails, respectively;
a first process chamber between the first and second guide rails, the first process chamber including a first gate facing the first guide rail;
a second process chamber between the first and second guide rails, the second process chamber including a second gate facing the second guide rail, the first and second process chambers having a space opposite to the first and second gates in common;
a first load lock chamber disposed along the first guide rail;
a second load lock chamber disposed along the second guide rail; and
a transport unit between the first and second load lock chambers.

18. A movable transfer chamber, comprising:
a chamber body having a gate for a substrate; and
a substrate-transferring unit in the chamber body,
wherein the movable transfer chamber is movable with respect to a process chamber and is combined with the process chamber under a vacuum condition to transfer the substrate.
